(19) United States
(12) Patent Application Publication
(10) Pub. No.: US 2007/0080422 A1
(43) Pub. Date: Apr. 12, 2007

(54) Semiconductor component with PN junction

(75) Inventors: Elmar Falck, Ottobrunn (DE); Herbert Pairitsch, Klagenfurt (AT); Hans-Joachim Schulze, Ottobrunn (DE)

Correspondence Address: Maginot, Moore & Beck;Chase Tower, Suite 3250, 11 Monument Circle, Indianapolis, IN, 46204, US

(73) Assignee: Infineon Technologies AG, Munich (DE)

(21) Appl. No.: 11/529,765

(22) Filed: Sep. 28, 2006

(30) Foreign Application Priority Data
Sep. 30, 2005 (DE) 102005047102.1-33

(51) Int. Cl. H01L 23/58

(52) U.S. Cl. 257/491

(57) ABSTRACT

A semiconductor component with a pn junction comprises a semiconductor body comprising a front side and an edge region. A pn junction is formed fashion in curved fashion in the edge region of the semiconductor body. An edge structure comprising depressions is also provided in the edge region of the semiconductor body. The depressions may comprise, for example, a number of capillaries which extend into the semiconductor body proceeding from the front side of the semiconductor body. In one suitable embodiment, the capillaries may be filled with a dielectric

### CROSS-REFERENCE TO RELATED APPLICATIONS

This application claims priority from German patent application number 10 2005 047 102.1, filed Sep. 30, 2005, the contents of which are incorporated herein by reference.

### FIELD

The present invention relates to a semiconductor component with a pn junction.

### BACKGROUND

In semiconductor components with a pn junction, in particular in power semiconductor components, it is necessary to take suitable measures to reduce the high electric field strengths occurring in the edge region of the pn junction in the off state of the component, in order to achieve a sufficiently high blocking capability of the semiconductor component.

A multiplicity of in particular planar edge terminations are known for this purpose. Examples thereof are floating field rings, field plates, JTE zones (JTE=junction termination extension), the resurf principle and also floating metal rings arranged above the edge region. These measures may in part also be used in combination with one another.

The totality of the measures for reducing the high electric field strengths in the edge region of the pn junction is also referred to as edge termination.

Such an edge termination in accordance with the prior art requires a large edge area and shows also the field boosting that occurs despite these measures.

In the case of field plates, particularly in the case of multistage field plates, particularly high electric field peaks can occur in their edge regions. This can give rise to electrical flashovers through a passivation layer arranged between adjacent field plates. Furthermore, an electrical breakdown may occur in the semiconductor zone below a field plate edge. These unfavorable effects already occur under static blocking loading and can also be considerably amplified when the component is switched on or off rapidly.

### SUMMARY

As disclosed herein, an embodiment of a semiconductor component comprises a semiconductor body including a front side and an edge region. A pn junction is formed in the semiconductor body between a first semiconductor zone of a first conduction type and a second semiconductor zone of a second conduction type complementary to the first conduction type. The pn junction has a curvature in the edge region of the semiconductor body and extending as far as a front side of the semiconductor body. A plurality of depressions are also formed in the semiconductor body spaced apart from one another in the edge region. The plurality of depressions may comprise, for example, capillaries, rings or trenches.

In one embodiment, the second semiconductor zone includes a first partial zone of the second conduction type and a second partial zone of the second conduction type, with the second partial zone having a weaker net dopant concentration than the first partial zone.

In one embodiment, the depressions extend into the semiconductor body proceeding from a front side. The depressions may be filled with a dielectric. The dielectric may be an oxide, such as an oxide of the same basic material of the semiconductor body.

The depressions may be arranged between the second semiconductor zone and a channel stopper of the first conduction type that proceeds from the front side of the semiconductor. In this embodiment, the channel stopper may be spaced apart from the second semiconductor zone.

In different embodiments, the depressions are differently arranged in the semiconductor body. In one embodiment, at least one of the depressions is arranged completely in the first semiconductor zone. In another embodiment, at least one of the depressions is arranged in both the first semiconductor zone and the second semiconductor zone. In yet another embodiment, at least one of the depressions is arranged completely in the second partial zone. In another embodiment, at least one of the depressions is arranged in both the first partial zone and the second partial zone. In yet another embodiment, at least one of the depressions is arranged such that it extends within the first semiconductor zone, the first partial zone and the second partial zone.

In addition to the depressions being arranged in different zones of the semiconductor body, the depressions may extend different distances into the semiconductor body. For example, in one embodiment the second semiconductor zone extends a first distance into the semiconductor body from the front side and at least one of the depressions extend farther than the first distance into the semiconductor body. In another embodiment, at least one of the depressions extends just as far into the semiconductor body from the front side as the second semiconductor zone. In yet another embodiment, at least one of the depressions does not extend as far into the semiconductor body from the front side as the second semiconductor zone.

In one embodiment, the depressions are capillaries arranged different lateral directions of the semiconductor body. The plurality of capillaries may include a first capillary arranged in a first azimuthal direction at a first azimuthal angle, a second capillary closest to the first capillary in the first azimuthal direction, a third capillary arranged in a second azimuthal direction at a second azimuthal angle, wherein the first capillary and the third capillary are spaced apart to the same extent from a lateral edge of the semiconductor body, a fourth capillary closest to the third capillary in the second azimuthal direction, wherein the second capillary and the fourth capillary are spaced apart to the same extent from the lateral edge of the semiconductor body, and a fifth capillary arranged in a third azimuthal direction at a third azimuthal angle, the third azimuthal angle greater than the first azimuthal angle and less than the second azimuthal angle, wherein the fifth capillary is spaced apart from the lateral edge of the semiconductor body farther than the second capillary and the fourth capillary but not as far as the first capillary and the third capillary.

The above described features and advantages, as well as others, will become more readily apparent to those of ordinary skill in the art by reference to the following detailed description and accompanying drawings.

### BRIEF DESCRIPTION OF THE DRAWINGS

Embodiments of the invention are explained in more detail below with reference to figures, in which:

FIG. 1 shows a vertical section through a section of a semiconductor component with a pn junction, in the edge region of which a number of depressions are arranged;

FIG. 2 shows an arrangement in accordance with FIG. 1 in which the depressions, proceeding from the surface of the semiconductor body of the component, extend not as far into the semiconductor body as the second semiconductor zone;

FIG. 3 shows an arrangement in accordance with FIGS. 1 and 2 in which the depressions extend further into the semiconductor body than the second semiconductor zone;

FIG. 4 shows an arrangement in accordance with FIG. 1 in which the second semiconductor zone is additionally preceded by a JTE zone extending as far as the front side of the semiconductor body;

FIG. 5 shows an arrangement in accordance with FIG. 4 in which the depressions, proceeding from the front side of the semiconductor body, extend not as far into the semiconductor body as the JTE zone;

FIG. 6 shows an arrangement in accordance with FIGS. 4 and 5 in which the depressions, proceeding from the front side of the semiconductor body, extend further into the latter than the JTE zone;

FIG. 7 shows an arrangement in accordance with FIG. 4 in which some of the depressions are arranged between the JTE zone and a channel stopper;

FIG. 8 shows a horizontal section through a section of a semiconductor component in accordance with FIG. 7 in a plane A through the depressions formed as capillaries, a plurality of capillaries in each case being arranged linearly one behind another in different lateral directions;

FIG. 9 shows a horizontal section according to FIG. 8, the capillaries arranged linearly one behind another in different lateral directions being offset with respect to one another in the radial direction; and

FIG. 10 shows a horizontal section through a section of a semiconductor component in accordance with FIG. 7 in a plane A through the depressions formed as rings.

In the figures, identical reference symbols designate identical parts with the same meaning.

### DESCRIPTION

A semiconductor component according to at least one embodiment of the invention includes a semiconductor body with a first semiconductor zone of a first conduction type and a second semiconductor zone of a complementary conduction type with respect to the first conduction type. A pn junction is formed between the first semiconductor zone and the second semiconductor zone, said pn junction extending in the edge region of the semiconductor body as far as the front side. Arranged in the edge region are a number of depressions which are spaced apart from one another, are formed as capillaries or as rings, for example, and which are at least partly, but preferably completely, filled with a dielectric.

The diameter of the capillaries is preferably 1 μm to 3 μm, their length is preferably 4 μm to 50 μm, and their distance from the closest capillary is preferably between 2 μm and 30 μm.

During the production of the depressions, for example by means of an etching process, charges are removed from the semiconductor body in the edge region, as a result of which the field strengths that occur are reduced and the breakdown voltage of the component is increased.

A further advantage of the depressions is that, for a predetermined reverse voltage strength of the component, the required edge width is reduced if the depressions are filled with a dielectric whose dielectric constant is less than the dielectric constant of the semiconductor material of the semiconductor body.

In accordance with at least one suitable embodiment of the invention, the second semiconductor zone may have a first partial zone and a second partial zone each of the second conduction type, the second partial zone having a weaker net dopant concentration than the first partial zone. The second partial zone is also referred to as JTE zone (JTE=junction termination extension).

In order to obtain an ideal blocking capability of such a component, the arrangement of the depressions is chosen such that the average quantity of charge in the JTE zone decreases toward the edge of the component, that is to say that the distance between the depressions of a JTE component preferably decreases toward the edge.

In this case, the average quantity of charge Q of the JTE zone is determined according to the following equation:

$$Q ( x , y ) = q \cdot {\int }_{{x}^{′} = x}^{x + Δ x} {\int }_{{y}^{′} = y}^{y + Δ y} {\int }_{{z}^{′} = 0}^{t} N ( {x}^{′} , {y}^{′} , {z}^{′} ) ⅆ {x}^{′} ⅆ {y}^{′} ⅆ {z}^{′} ,$$

where x denotes a first lateral direction, y denotes a second lateral direction, and z denotes the vertical direction of the semiconductor body with respect to the front side, and N(x, y, z) denotes the net dopant concentration in the JTE zone. The variable q designates the elementary charge and has a positive sign for a JTE zone with p-type net doping and a negative sign for a JTE zone with n-type net doping. The integration in the vertical direction z is effected over the thickness t of the JTE zone.

In the case where the depressions are formed as capillaries, the integration intervals [x; x+Δx] for the first lateral direction x and [y; y+Δy] for the second lateral direction y are to be chosen with a magnitude such that a plurality of capillaries are arranged in the range given by said intervals.

In accordance with at least one suitable embodiment of the invention, the depressions may be formed as coaxial annuli having different diameters. In this case, in the above equation it is necessary to replace the quantity of charge Q by the quantity of charge Q per length and the lateral directions x, y by the radial direction r perpendicular to and proceeding from the common axis of the coaxial annuli:

$$\frac{Q ( r )}{Length} = q \cdot {\int }_{{r}^{′} = r}^{r + Δ r} {\int }_{{z}^{′} = 0}^{t} N ( {x}^{′} , {y}^{′} , {z}^{′} ) ⅆ {x}^{′} ⅆ {y}^{′} ⅆ {z}^{′} .$$

In this case, the integration interval [r; r+Δr] for the lateral direction r has to be chosen with a magnitude such that a plurality of coaxial annuli are arranged in the range given by said interval.

In such a component with JTE zone, the depressions may also be arranged entirely or only in sections in the JTE zone.

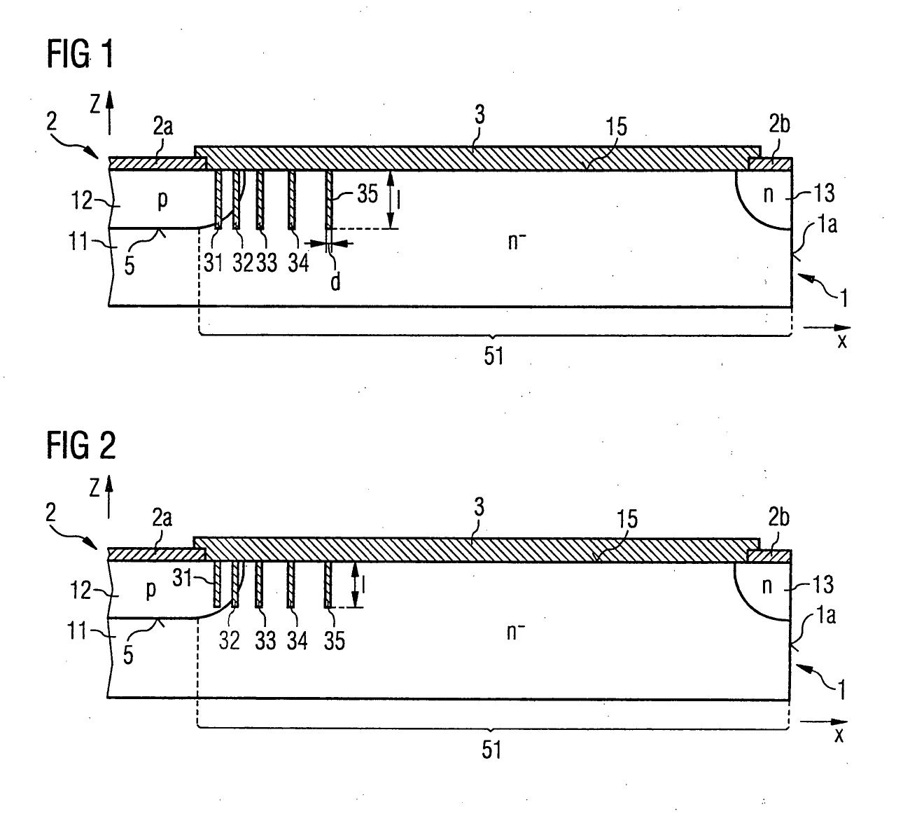

With reference now to FIG. 1, a vertical section of a semiconductor component is shown through a section comprising the edge region of the semiconductor component.

The semiconductor component has a semiconductor body 1, on which a patterned metallization 2 and also a passivation layer 3 are arranged.

The semiconductor body 1 comprises a weakly n-doped substrate, for example a wafer, into which a p-doped well 12 and an n-doped well 13 have been indiffused proceeding from a front side 15 of the semiconductor body 1.

As a result, the semiconductor body 1 comprises a weakly n-doped first semiconductor zone 11, a p-doped second semiconductor zone 12 and also an n-doped channel stopper 13.

A pn junction 5 is formed between the first semiconductor zone 11 and the second semiconductor zone 12. Said pn junction runs essentially parallel to the front side 15. However, the pn junction has an edge curvature in the direction of the front side 15 and extends as far as said front side 15. The region of the semiconductor body 1 which comprises the edge curvature and extends in the lateral direction x as far as the lateral edge 1a of the semiconductor body 1 is designated hereafter as edge region 51.

In the off state of the component, the edge region 51 has an excessively increased electric field that has to be reduced by suitable measures to an extent such that no voltage breakdowns occur in particular in the semiconductor material and in the passivation layer 3.

For this purpose, a number of depressions 31 to 35 spaced apart from one another are arranged in the semiconductor body 1, and they extend into the semiconductor body 1 proceeding from the front side 15 thereof. The depressions may be formed for example as capillaries or suitably, as annular trenches. In the case of capillaries, the latter have a longitudinal axis perpendicular to the front side 15.

The thickness d of the depressions in the first lateral direction x or the diameter d of the capillaries is preferably 1 μm to 3 μm, and the length l of the depressions in the vertical direction z is preferably 4 μm to 50 μm.

In the present exemplary embodiment, the depressions 31 to 35, proceeding from the front side 15 of the semiconductor body 1, extend just as far into the latter as the second semiconductor zone 12.

While the depressions 33, 34, 35—spaced apart from the second semiconductor zone 12—are arranged completely in the region of the first semiconductor zone 11 and also between the second semiconductor zone 12 and the channel stopper 13, the depressions 31, 32 are in each case arranged in sections both in the first semiconductor zone 11 and in the second semiconductor zone 12.

FIG. 2 shows an exemplary embodiment according to FIG. 1, with the difference that the depressions 31 to 35, proceeding from the front side 15 of the semiconductor body 1, extend not as far into said semiconductor body as the second semiconductor zone 12.

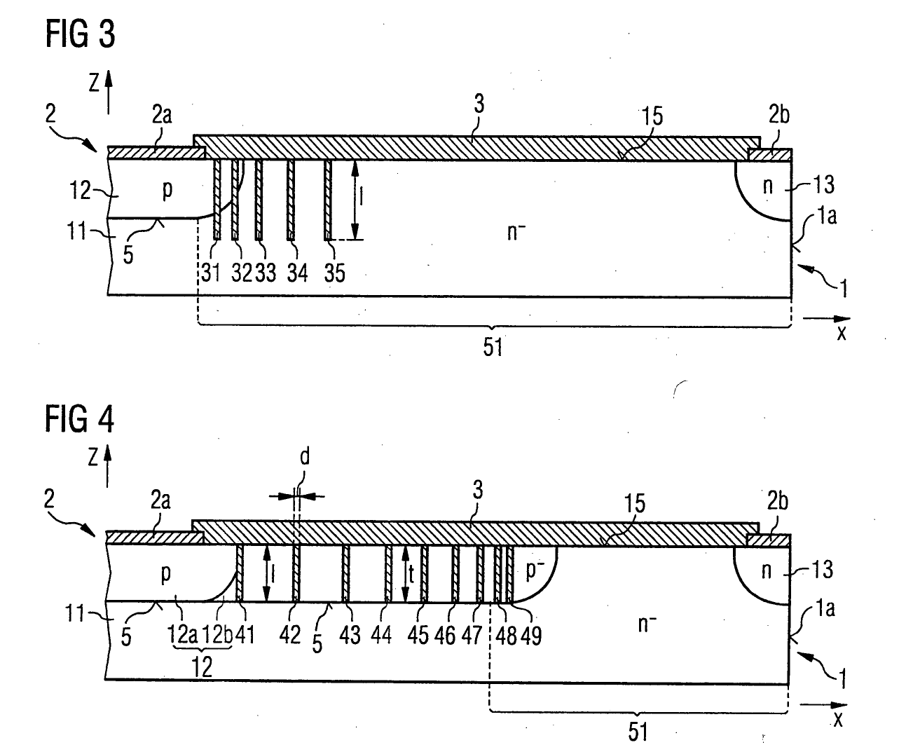

In a corresponding manner, the arrangement in accordance with FIG. 3 shows that the depressions 31 to 35, proceeding from the front side 15 of the semiconductor body 1, can also extend further into the latter than the second semiconductor zone 12.

FIG. 4 shows a semiconductor component according to the semiconductor component in accordance with FIG. 1, the second semiconductor zone 12 comprising a first partial zone 12a and a second partial zone 12b. Both partial zones 12a, 12b are p-doped, the second partial zone 12b having a weaker net dopant concentration than the first partial zone 12a. The second partial zone 12b is also referred to as JTE zone.

The JTE zone 12b extends into the semiconductor body 1 proceeding from the front side 15 thereof and adjoins both the first semiconductor zone 11 and the first partial zone 12a.

The net dopant concentration of the JTE zone 12b may either be constant in the first lateral direction x or increase or decrease monotonically or strictly monotonically in the first lateral direction x as in a VLD edge termination (VLD=variation of lateral doping) with increasing distance from the first partial zone 12a.

The extent t of the JTE zone 12b in the vertical direction v may be equal in magnitude, larger or smaller than the extent of the zone 12a in the vertical direction v.

A further difference with respect to the exemplary embodiment in accordance with FIG. 1 consists in the spatial distribution of the depressions. In the exemplary embodiment in accordance with FIG. 4, a depression 41 is provided which is arranged in sections both in the first semiconductor zone 12a and in the JTE zone 12b. The depressions 42 to 47, by contrast, are arranged completely in the JTE zone 12b. Furthermore, the depressions 48 and 49 are in each case arranged in sections both in the first semiconductor zone 11 and in the JTE zone 12b.

The depressions 41 to 47, proceeding from the front side 15 of the semiconductor body 1, extend just as far into the latter as the first partial zone 12a and the JTE zone 12b.

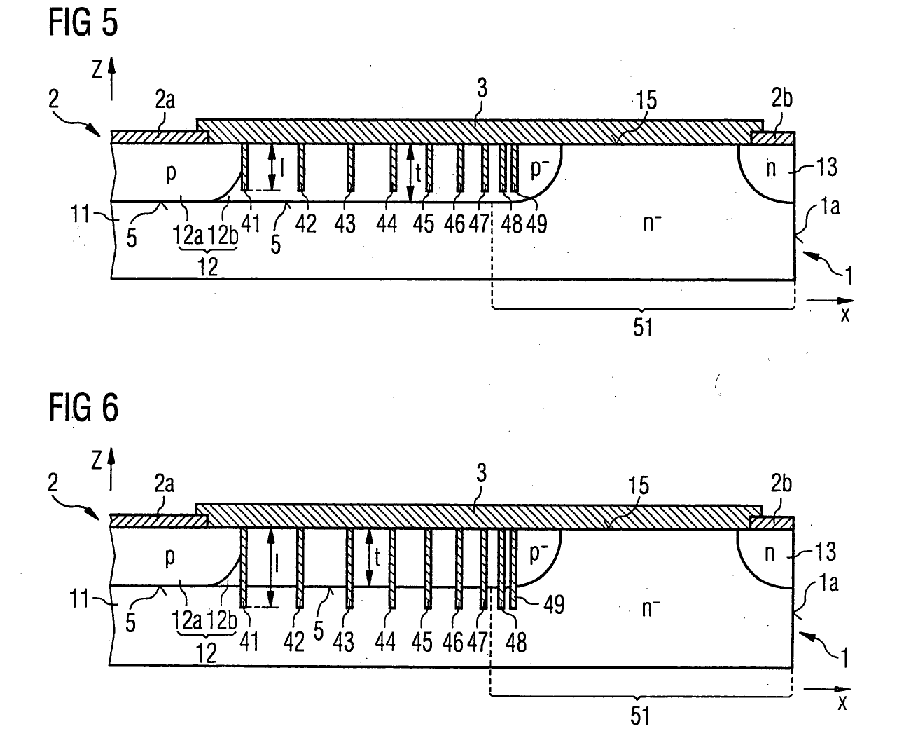

The exemplary embodiment in accordance with FIG. 5 corresponds to the exemplary embodiment in accordance with FIG. 4, with the difference that the depressions 41 to 49, proceeding from the front side 15 of the semiconductor body 1, extend not as far into said semiconductor body as the first partial zone 12a and the JTE zone 12b.

The exemplary embodiment in accordance with FIG. 6 furthermore shows an arrangement in accordance with FIGS. 4 and 5, with the difference that the depressions 41 to 49, proceeding from the front side 15 of the semiconductor body 1, extend further into the latter than the first partial zone 12a and the JTE zone 12b.

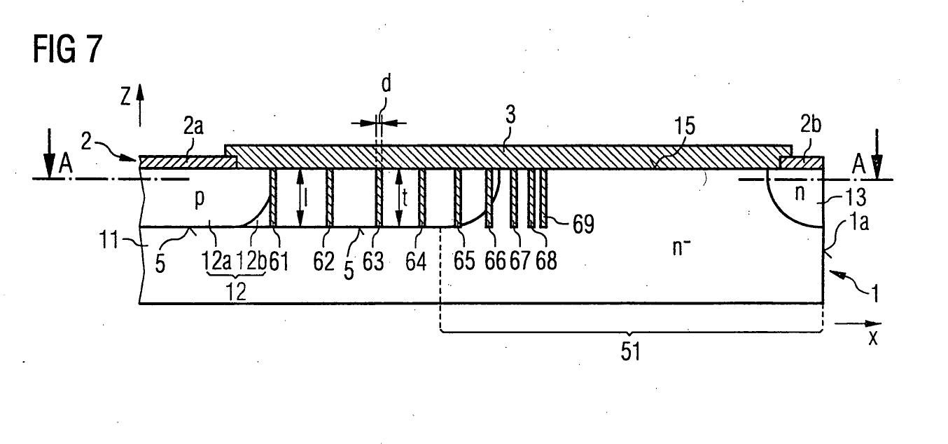

FIG. 7 shows a component with depressions 61 to 69, of which the depression 61 is arranged in sections in the first partial zone 12a and in sections in the second partial zone 12b while the depressions 62 to 64 are arranged completely in the second partial zone 12b. The depressions 65, 66 in turn are in each case arranged in sections in the second partial zone 12b and in the first semiconductor zone 11. Finally, the depressions 67, 68, 69—spaced apart from the JTE zone 12b—are arranged completely in the first semiconductor zone 11.

In all the components with a JTE zone 12b explained above, the JTE zone 12b has a net dopant dose which is higher before the production of the depressions than the net dopant dose of a corresponding component with JTE zone in accordance with the prior art without depressions.

In a component according to at least one embodiment of the invention, the lengths and the cross-sectional areas of the depressions, or—in the case of depressions formed as cylindrical capillaries—the diameters thereof as well, may vary in particular depending on the position of the depressions in the lateral direction. By way of example, the cross-sectional areas or diameters d and/or the vertical dimensions l of the depressions may increase or decrease with increasing distance of the depressions from the first semiconductor zone (FIGS. 1 to 3) or with increasing distance from the first partial zone (FIGS. 4 to 7).

The semiconductor body 1, in particular the second semiconductor zone 12, the partial zones 12a, 12b thereof, and also the channel stopper 13 are preferably formed in rotationally symmetrical fashion or have a four-fold rotational symmetry with respect to an axis of symmetry running perpendicular to the front side 15.

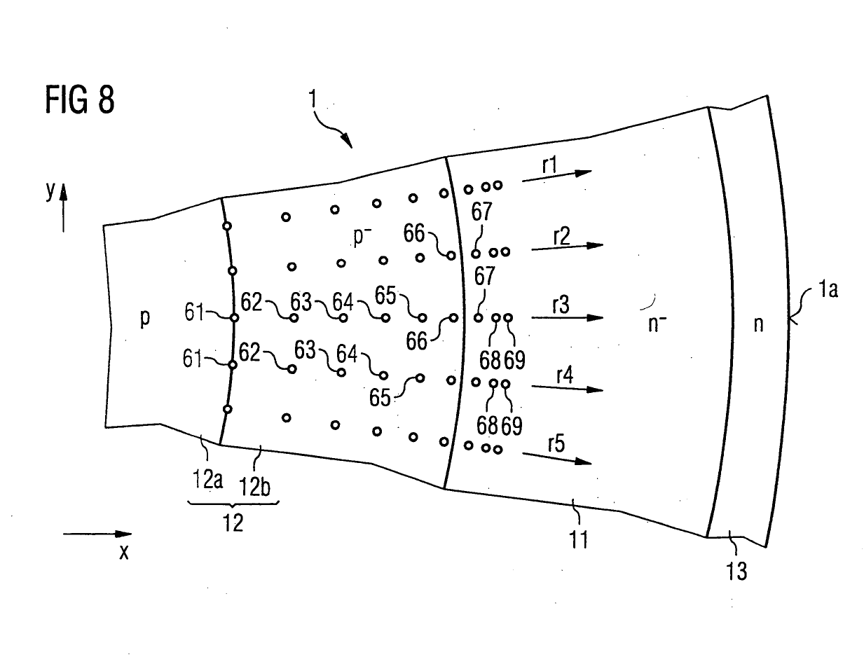

The FIGS. 8, 9 and 10 show by way of example various preferred possibilities for the spatial arrangement of depressions in a sectional plane A of the component in accordance with FIG. 7. FIGS. 8, 9, 10 each show a section of a semiconductor body with a circular cross section.

In the exemplary embodiment in accordance with FIG. 8, the depressions 61, 62, 63, 64, 65, 66, 67, 68, 69 are formed as capillaries. In this case, capillaries 61 to 69 are in each case arranged linearly one behind another in different lateral directions r1, r2, r3, r4 and r5.

Furthermore, a plurality of capillaries are in each case arranged in annulus-like fashion, capillaries provided with the same reference symbol being arranged along the same annulus and being at the same distance from the lateral edge la of the semiconductor body 1.

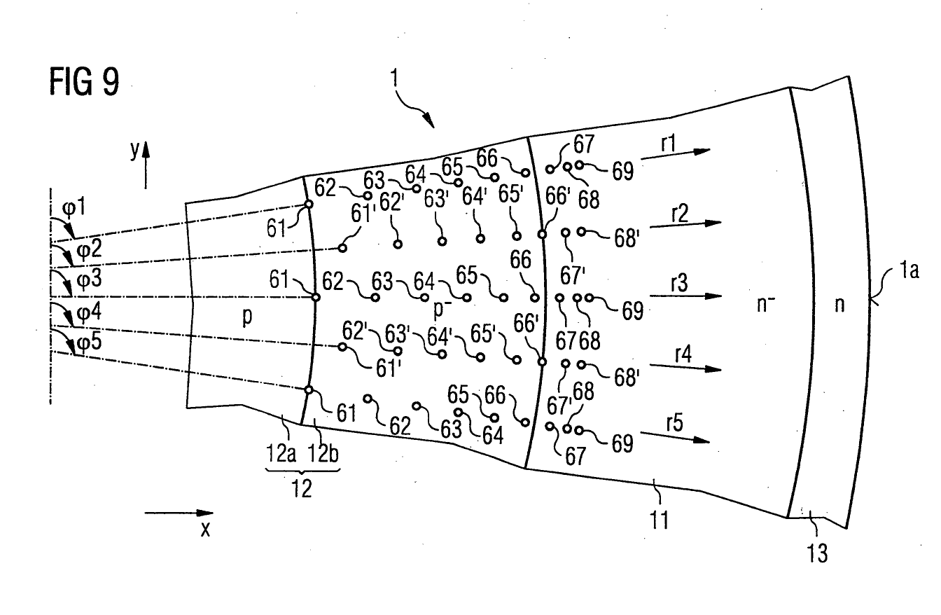

A further embodiment of a spatial arrangement of depressions formed as capillaries is shown in FIG. 9. The exemplary embodiment corresponds to the exemplary embodiment in accordance with FIG. 8, but the capillaries arranged linearly one behind another are respectively offset depending on the lateral direction according to the relevant lateral direction. Capillaries 61 to 69 are in each case arranged linearly one behind another in different lateral directions r1, r3, r5, which run at azimuthal angles φ1, φ3 and φ5, respectively, relative to the second lateral direction y.

Correspondingly, capillaries 61′ to 68′ are in each case arranged linearly one behind another in other lateral directions r2 and r4, which run at azimuthal angles φ2 and φ4, respectively, relative to the second lateral direction y.

By way of example, a first capillary 61 and a second capillary 62 closest to the latter in the lateral direction r1 are arranged in the lateral direction r1.

Furthermore, a first capillary 61 and a second capillary 62 closest to the latter in the lateral direction r3 are arranged in the lateral direction r3.

A fifth capillary 61′ is arranged in the lateral direction r2, the associated azimuthal angle φ2 of which is greater than the azimuthal angle φ1 of the lateral direction r1 and less than the azimuthal angle φ3 of the lateral direction r3, said fifth capillary being spaced apart from the lateral edge la of the semiconductor body 1 further than the second and fourth capillaries 62, but not as far as the first and third capillaries 61.

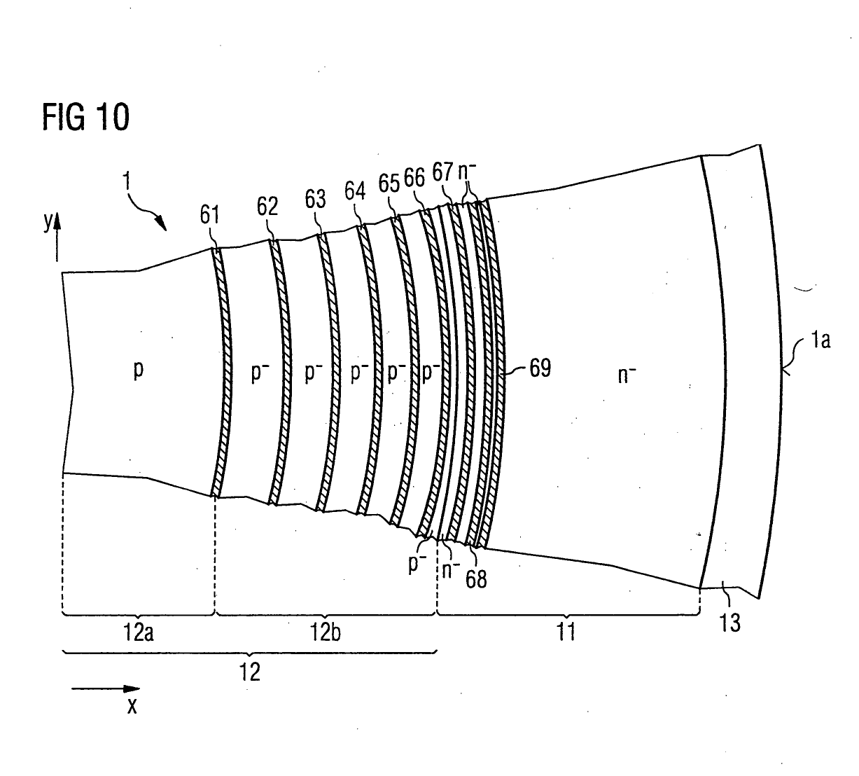

FIG. 10 also shows a cross section through a section of the arrangement in accordance with FIG. 7 in a plane A.

In this case, the depressions 61 to 69 are not formed as capillaries, but rather as coaxial rings having different diameters, the distance between adjacent rings increasing with increasing distance of the rings from the lateral edge 1a of the semiconductor body 1.

The exemplary embodiments of the configuration and distribution of the depressions as shown in FIGS. 8, 9 and 10 are not restricted to the component with VLD zone shown.

In principle, the arrangements shown can be used in the case of components without a VLD zone, for example in the case of components in accordance with FIGS. 1 to 6.

In components both with and without a VLD zone, depressions may be arranged in the first semiconductor zone 11 and/or in the second semiconductor zone 12 and/or—in components with VLD zone—in the first partial zone 12a and/or the second partial zone 12b.

Furthermore, the semiconductor bodies may also have, perpendicular to the vertical direction, rectangular, in particular square, cross sections with rounded corners instead of the circular cross sections described.

While the invention disclosed herein has been described in terms of several preferred embodiments, there are numerous alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is

1. A semiconductor comprising:
a semiconductor body including a front side and an edge region;
a pn junction formed in the semiconductor body between a first semiconductor zone of a first conduction type and a second semiconductor zone of a second conduction type complementary to the first conduction type, wherein the pn junction has a curvature in the edge region of the semiconductor body and extends in the edge region as far as the front side of the semiconductor body; and
a plurality of capillaries spaced apart from one another in the edge region.

2. The semiconductor component of claim 1 wherein the capillaries have a longitudinal axis perpendicular to the front side of the semiconductor body.

3. The semiconductor component of claim 1 wherein the capillaries are filled with a dielectric.

4. The semiconductor component of claim 3 wherein the dielectric is an oxide.

5. The semiconductor component of claim 4 wherein the oxide is an oxide of a basic material of the semiconductor body.

6. The semiconductor component of claim 1 wherein at least one of the capillaries extends into the semiconductor body proceeding from the front side.

7. The semiconductor component of claim 6 wherein each of the capillaries extends into the semiconductor body proceeding from the front side.

8. The semiconductor component of claim 1 wherein the capillaries have a diameter of 1 μm to 3 μm.

9. The semiconductor component of claim 1 wherein the distance between a first capillary and a second capillary closest to the first capillary is 2 μm to 30 μm.

10. The semiconductor component of claim 1 wherein the capillaries have a length of 4 μm to 50 μm.

11. The semiconductor component of claim 1 wherein at least one of the capillaries is arranged between the second semiconductor zone and a channel stopper of the first conduction type, wherein the channel stopper is spaced apart from the second semiconductor zone.

12. The semiconductor component of claim 11 wherein the channel stopper extends into the semiconductor body proceeding from the front side.

13. The semiconductor component of claim 1 wherein at least one of the capillaries is arranged completely in the first semiconductor zone.

14. The semiconductor component of claim 1 wherein at least one of the capillaries is arranged in both the first semiconductor zone and the second semiconductor zone.

15. The semiconductor component of claim 1 wherein the second semiconductor zone includes a first partial zone of the second conduction type and a second partial zone of the second conduction type, wherein the second partial zone has a weaker net dopant concentration than the first partial zone.

16. The semiconductor component of claim 15 wherein at least one of the capillaries is arranged completely in the second partial zone.

17. The semiconductor component of claim 15 wherein at least one of the capillaries is arranged in both the first partial zone and the second partial zone.

18. The semiconductor component of claim 15 wherein at least one of the capillaries is arranged such that it extends within the first semiconductor zone, the first partial zone and the second partial zone.

19. The semiconductor component of claim 1 wherein the second semiconductor zone extends no farther than a first distance into the semiconductor body from the front side and wherein at least one of the capillaries extends a second distance greater than the first distance into the semiconductor body from the front side.

20. The semiconductor component of claim 1 wherein at least one of the capillaries extends just as far into the semiconductor body from the front side as the second semiconductor zone.

21. The semiconductor component of claim 1 wherein at least one of the capillaries does not extend as far into the semiconductor body from the front side as the second semiconductor zone.

22. The semiconductor component of claim 1 wherein each of the capillaries is arranged in a different lateral direction of the semiconductor body.

23. The semiconductor component of claim 22 wherein the plurality of capillaries include
a first capillary arranged in a first azimuthal direction at a first azimuthal angle,
a second capillary closest to the first capillary in the first azimuthal direction,
a third capillary arranged in a second azimuthal direction at a second azimuthal angle, wherein the first capillary and the third capillary are spaced apart to the same extent from a lateral edge of the semiconductor body,
a fourth capillary closest to the third capillary in the second azimuthal direction, wherein the second capillary and the fourth capillary are spaced apart to the same extent from the lateral edge of the semiconductor body, and
a fifth capillary arranged in a third azimuthal direction at a third azimuthal angle, the third azimuthal angle greater than the first azimuthal angle and less than the second azimuthal angle, wherein the fifth capillary is spaced apart from the lateral edge of the semiconductor body farther than the second capillary and the fourth capillary but not as far as the first capillary and the third capillary.

24. The semiconductor component of claim 1 wherein the capillaries are arranged in annular fashion along coaxial rings having different ring diameters.

25. The semiconductor component of claim 24 wherein the capillaries arranged along each of the coaxial rings are spaced apart equidistantly from one another at a predetermined distance.

26. A semiconductor comprising:
a semiconductor body including a front side and an edge region;
a pn junction formed in the semiconductor body between a first semiconductor zone of a first conduction type and a second semiconductor zone of a second conduction type complementary to the first conduction type, wherein the pn junction has a curvature in the edge region of the semiconductor body; and
a plurality of depressions spaced apart from one another in the edge region;
wherein the second semiconductor zone includes a first partial zone of the second conduction type and a second partial zone of the second conduction type, the second partial zone having a weaker net dopant concentration than the first partial zone.

27. The semiconductor component of claim 26 wherein the depressions are filled with a dielectric.

28. The semiconductor component of claim 27 wherein the dielectric is an oxide.

29. The semiconductor component of claim 28 wherein the oxide is an oxide of a basic material of the semiconductor body.

30. The semiconductor component of claim 26 wherein at least one of the depressions extends into the semiconductor body proceeding from the front side.

31. The semiconductor component of claim 30 wherein each of the depressions extends into the semiconductor body proceeding from the front side.

32. The semiconductor component of claim 26 wherein the depressions have a width of 1 μm to 3 μm.

33. The semiconductor component of claim 26 wherein the distance between a first depression and a second depression closest to the first depression is 2 μm to 30 μm.

34. The semiconductor component of claim 26 wherein the depressions have a depth of 4 μm to 50 μm.

35. The semiconductor component of claim 26 wherein at least one of the depressions is arranged between the second semiconductor zone and a channel stopper of the first conduction type, wherein the channel stopper is spaced apart from the second semiconductor zone.

36. The semiconductor component of claim 35 wherein the channel stopper extends into the semiconductor body proceeding from the front side.

37. The semiconductor component of claim 26 wherein at least one of the depressions is arranged completely in the first semiconductor zone.

38. The semiconductor component of claim 26 wherein at least one of the depressions is arranged in both the first semiconductor zone and the second semiconductor zone.

39. The semiconductor component of claim 38 wherein at least one of the depressions is arranged completely in the second partial zone.

40. The semiconductor component of claim 38 wherein at least one of the depressions is arranged in both the first partial zone and in the second partial zone.

41. The semiconductor component of claim 38 wherein at least one of the depressions is arranged such that it extends within the first semiconductor zone, the first partial zone and the second partial zone.

42. The semiconductor component of claims 26 wherein the second semiconductor zone extends no farther than a first distance into the semiconductor body from the front side, and wherein at least one of the depressions extends a second distance greater than the first distance into the semiconductor body from the front side.

43. The semiconductor component of claim 26 wherein at least one of the depressions extends just as far into the semiconductor body from the front side as the second semiconductor zone.

44. The semiconductor component of claim 26 wherein at least one of the depressions does not extend as far into the semiconductor body from the front side as the second semiconductor zone.

45. The semiconductor component of claim 26 wherein at least two of the plurality of depressions are formed as coaxial rings.

46. The semiconductor component of claim 26 wherein the first conduction type is “n” and the second conduction type is “p”.

47. The semiconductor component of claim 26 wherein the first conduction type is “p” and the second conduction type is “n”.
